(19) United States
(12) Patent Application Publication
(10) Pub. No.: US 2024/0199925 A1
(43) Pub. Date: Jun. 20, 2024

(54) ELECTRICALLY CONDUCTIVE ADHESIVE COMPOSITION FOR BONDING SOLAR CELLS

(71) Applicant: Henkel AG & Co. KGaA, Duesseldorf (DE)

(72) Inventors: Shasha Duan, Shanghai (CN); Jibing Fu, Shanghai (CN); Yong Liu, Shanghai (CN); Bo Dong, Shanghai (CN); Junxi Wu, Shanghai (CN); Lei Fang, Shanghai (CN)

(21) Appl. No.: 18/589,316

(22) Filed: Feb. 27, 2024

Related U.S. Application Data
(63) Continuation of application No. PCT/CN2021/115002, filed on Aug. 27, 2021.

(51) Int. Cl. C09J 9/02; C09J 5/00; C09J 11/04; C09J 11/08; C09J 163/10; H01B 1/22; H01L 31/05

(52) U.S. Cl. CPC C09J 9/02; C09J 5/00; C09J 11/04; C09J 11/08; C09J 163/10; H01B 1/22; H01L 31/0512; C09J 2421/00; C09J 2463/00

(57) ABSTRACT

The present invention provides an electrically conductive adhesive composition comprising (A) at least one non-toughened epoxy resin, (B) optionally at least one toughened epoxy resin, (C) at least one imidazole compound, (D) at least one latent amine curing agent other than imidazole compound, (E) at least one silver filler having a D50 particle size of no more than 20 μm, and (F) at least one silver filler having a D50 particle size of from 20 to 100 μm.

### TECHNICAL FIELD

The present invention relates to an electrically conductive adhesive composition for bonding solar cells, to the cured product and to the use thereof.

### BACKGROUND OF THE INVENTION

At present, a solar cell or photovoltaic (PV) cell is an electrical device that converts the energy of light directly into electricity by the photovoltaic effect. Solar cells are the building blocks of the PV modules, otherwise known as solar panels, in order to increase the voltage delivered by individual solar cells.

In a typical conventional PV module, the PV cells are electrically connected in serial or parallel via conductive ribbons to form a PV string array. The common method of connecting these PV cells is through soldering process, referred to as tabbing and stringing. Once a PV string array is formed, the ribbons of individual PV strings are connected together by a module busbar to establish a circuit, thus completing the PV module electrical circuitry.

In the case of a shingled PV module, one PV cell is partially overlapped onto another PV cell. During shingling process, the rear busbar contact area of a PV cell comes into contact with the front busbar contact area of another PV cell. This step can be repeated multiple times to form a PV string which are connected to each other to establish an electrical connection.

The PV cell overlapping process can be made possible by directly overlapping the busbars of the PV cells on top of each other to establish electrical connection, but the downside of this method is that these cells are susceptible to misalignment during the assembly process or post assembly process. When the positions of these PV cells are not secured properly, any influence of external force, whether it is caused by equipment vibration, vacuum pick-up process or even finished product reliability testing phase, can greatly influence the positioning of the PV cells assembly. In some instances, electrically conductive adhesives are introduced between the busbars to provide a more reliable connection, both mechanically and electrically.

These electrically conductive adhesives materials are normally manufactured with conductive fillers. Electrically conductive adhesive as a material to bond the PV cells together have the advantage that they overcome mechanical stresses.

Prior art describes various different kind of electrically conductive adhesives, which can be used in PV cells and to form PV modules. Many of these electrically conductive adhesives are epoxy or silicone-based adhesives. However, with an increasingly trend of smaller and smaller overlapping region, such as 1.0 mm in width or even less, although the adhesives described in the prior art before are able to reach desired electrical properties when cured, there is one limitation that when they are introduced between the busbars of PV cells tends to squeeze out of the overlapping region. This leads to PV cell shunting, hotspot failures and other reliability issues. The solutions to address such squeeze-out issue described in the prior art are mainly focused on developing printing or dispensing techniques, such as to optimize stencil design, using smaller nozzle, etc.

In view of the above, there is still a need for an electrically conductive adhesive composition which is able to not squeeze out of the overlapping area with a smaller PV cells during the shingling process while exhibits good volume resistance and contact resistance when cured.

### SUMMARY OF THE INVENTION

According to a first aspect of the invention, disclosed herein is an electrically conductive adhesive composition comprising:
(A) at least one non-toughened epoxy resin,
(B) optionally at least one toughened epoxy resin,
(C) at least one imidazole compound,
(D) at least one latent amine curing agent other than imidazole compound,
(E) at least one silver filler having a D50 particle size of no more than 20 μm, and
(F) at least one silver filler having a D50 particle size of from 20 to 100 μm.

According to a second aspect of the invention, a cured product of the electrically conductive adhesive composition according to the present invention is provided herein.

According to a third aspect of the invention, provided herein is a bonded assembly comprising two substrates aligned in a spaced apart relationship, each of which having an inwardly facing surface and an outwardly facing surface, wherein between the inwardly facing surfaces of each of the two substrates an electrically conductive bond is formed by the cured product of the electrically conductive adhesive composition of the present invention.

According to a fourth aspect of the invention, a PV module is provided, comprising a series-connected string of at least two PV cells in a shingle pattern having an electrically conductive adhesive composition of the present invention bonding between at least two PV cells.

According to a fifth aspect of the invention, a method of interconnecting two PV cells is provided, comprising:
(1) providing a first PV cell on a flat surface;
(2) applying an electrically conductive adhesive composition of the present invention on the front busbar of the first PV cell;
(3) providing a second PV cell in a partial overlapping manner, such that the rear busbar of the second PV cell comes into contact with the front busbar of the first PV cell having the said electrically conductive adhesive composition bonding in between, and
(4) curing the said electrically conductive adhesive composition.

According to the sixth aspect of the invention, use of the electrically conductive adhesive composition according to the present invention or the cured product according to the present invention in the manufacturing of photovoltaic modules or solar panels.

Other features and aspects of the subject matter are set forth in greater detail below.

### DETAILED DESCRIPTION OF THE INVENTION

It is to be understood by one of ordinary skill in the art that the present invention is a description of exemplary embodiments only and is not intended as limiting the broader aspects of the present invention. Each aspect so described may be combined with any other aspect or aspects unless clearly indicated to the contrary. In particular, any feature indicated as being preferred or advantageous may be combined with any other feature or features indicated as being preferred or advantageous.

Unless specified otherwise, in the context of the present invention, the terms used are to be construed in accordance with the following definitions.

Unless specified otherwise, as used herein, the terms “a”, “an” and “the” include both singular and plural referents.

The term “photovoltaic” or PV in short, may refer to the conversion of light into electricity using semi-conductor materials that exhibits photovoltaic effect. Photovoltaic cells and photovoltaic modules can also be regarded as solar cells and solar modules.

The term “photovoltaic cell” or “PV cell” in short, may refer to the semiconductor material that exhibit photovoltaic effect i.e. converting light into electricity. Photovoltaic cells can also be regarded as solar cells.

The term “photovoltaic module” or PV module in short may constitute PV cells which are interconnected and are encapsulated into an assembly that generates solar electricity. Photovoltaic modules can also be regarded as solar modules or solar panels.

The term “shingled” may refer to photovoltaic cells which are shingled together. Shingled may refer to a PV cell which is partially overlapped onto another PV cell. During shingling process, the back busbar contact area of a PV cell comes into contact with the front busbar contact area of another PV cell.

The term “string” may refer to two or more photovoltaic cells that are connected in series to form a chain or a string of PV cells.

The term “busbar” may refer to a conductive element or electrode which is printed on the front and rear of a PV cell. The purpose of a busbar is to conduct the direct current produced by the PV cell from the incoming photons. Busbars are used to conduct electric current from grid fingers, neighbouring PV cells and/or external circuitry.

The terms “comprising” and “comprises” as used herein are synonymous with “including”, “includes” or “containing”, “contains”, and are inclusive or open-ended and do not exclude additional, non-recited members, elements or process steps.

The term “room temperature” as used herein refers to a temperature of about 20° C. to about 25° C., preferably about 25° C.

The term “substrate”, as used herein, preferably refers to an electrode, wherein the inwardly facing surface of the electrode is in contact with the cured product of the adhesive of the present invention.

The term “surface area”, as used herein, refers to the total surface area based on the macroscopic dimensions of the surface, wherein the roughness of the surface is neglected.

Unless specified otherwise, the recitation of numerical end points includes all numbers and fractions subsumed within the respective ranges, as well as the recited end points.

All references cited in the present specification are hereby incorporated by reference in their entirety.

Unless otherwise defined, all terms used in the present invention, including technical and scientific terms, have the meaning as commonly understood by one of the ordinary skilled in the art to which this invention belongs.

In one aspect, the present disclosure is generally directed to an electrically conductive adhesive composition:
(A) at least one non-toughened epoxy resin,
(B) optionally at least one toughened epoxy resin,
(C) at least one imidazole compound,
(D) at least one latent amine curing agent other than imidazole compound,
(E) at least one silver filler having a D50 particle size of no more than 20 μm, and
(F) at least one silver filler having a D50 particle size of from 20 to 100 μm.

### Non-Toughened Epoxy Resin

According to the present invention, the electrically conductive adhesive composition comprises (A) at least one non-toughened epoxy resin.

As used herein, the term “non-toughened epoxy resin” is understood to have not undergo a toughening treatment, either physically or chemically.

In some embodiments, the non-toughened epoxy resin can be selected from non-toughened epoxy resin having no (meth)acrylate group, non-toughened epoxy resin containing (meth)acrylate group, halides thereof and hydrides thereof, and combinations of the above.

Examples of non-toughened epoxy resin having no (meth)acrylate group include bisphenol A based diglycidyl ethers, bisphenol F based diglycidyl ethers, bisphenol S based diglycidyl ethers, bisphenol Z based diglycidyl ethers, cyclopentadiene epoxy resin, halides thereof and hydrides thereof, and combinations of the above, preferably bisphenol A based diglycidyl ethers, bisphenol F based diglycidyl ethers, and combinations thereof.

Examples of non-toughened epoxy resin containing (meth)acrylate group include glycidyl (meth)acrylate, 4-hydroxybutyl (meth)acrylate glycidyl ether, 3,4-epoxycyclohexyl (meth)acrylate, 3,4-epoxycyclohexylmethyl (meth)acrylate, halides thereof and hydrides thereof, and combinations of the above, preferably glycidyl (meth)acrylate.

In preferred embodiments, the component (A) is a combination of at least one non-toughened epoxy resin having no (meth)acrylate group and at least one non-toughened epoxy resin containing (meth)acrylate group, preferably a combination of bisphenol A based diglycidyl ethers, bisphenol F based diglycidyl ethers and glycidyl (meth)acrylate.

In preferred embodiments, the component (A) is at least one non-toughened epoxy resin having molecular weight of from 1000 to 30,000 g/mol, more preferably a combination of at least one non-toughened epoxy resin having molecular weight of from 8000 to 30,000 g/mol and at least one non-toughened epoxy resin having molecular weight of from 100 to 1000 g/mol. When curing, the non-toughened epoxy resin having molecular weight of from 8000 to 30,000 g/mol could encapsulate the non-toughened epoxy resin having molecular weight of from 100 to 1000 g/mol to prevent resins from outflowing on the substrate, which can effectively decrease the so-called “bleeding” effect during the manufacturing process and improve the appearance of the cured adhesive compositions.

Examples of commercially available products of non-toughened epoxy resin include Epon 828, Epon 826, Epon 862, (all from Hexion Co., Ltd.), DER 331, DER 383, DER 332, DER 330-EL, DER 331-EL, DER 354, DER 321, DER 324, DER 29, DER 353 (all from Dow Chemical Co., Ltd.), JER YX8000, JER RXE21, JER YL 6753, JER YL6800, JER YL980, JER 825, JER 630 (all from Japan Epoxy Resins Co., Ltd.), EP 4300E, Epichlon 830, Epichlon 830S, Epichlon 835, Epichlon EXA-830CRP, Epichlon EXA-830LVP, Epichlon EXA-835LV (all from DIC Corporation), Epotohto ZX 1059 (from Nippon Steel chemical Co., Ltd) and MARPROOF G-0150M (from NOF Corporation).

According to the present invention, the component (A) may present in an amount of from 5% to 30% by weight, preferably from 12% to 20% by weight, based on the total weight of the composition.

### Toughened Epoxy Resin

According to the present invention, the electrically conductive adhesive composition may optionally comprise (A) at least one toughened epoxy resin.

In some embodiments, toughened epoxy resin used in the present invention can be epoxy resin toughened by at least one toughening agent selected from core shell rubber, liquid butadiene rubber, and combinations thereof.

As used herein, the term “toughened epoxy resin” refers to an epoxy resin undergoes toughening modification or treatment by a toughening agent based on either physical or chemical mechanism. By a physical way, the toughening agent may be physically pre-dispersed in the epoxy resin matrix to form toughened epoxy resin. While through a chemical mechanism, the toughening agent may be reactive and capable of reacting substantially to the epoxy resin matrix to form chemical bonds and hence generate toughened epoxy resin. Preferably, the toughened epoxy resin used in the present invention is an epoxy resin having two or more glycidyl groups modified by toughening agent.

Suitable examples of the said epoxy resin having two or more glycidyl groups are the di-, tri-, or tetra-functional epoxy resins, preferably difunctional epoxy resins, for example bisphenol A based diglycidyl ethers and bisphenol F based diglycidyl ethers. The toughening agent used to toughen the said epoxy resin can be core-shell rubber particles (physical way), or liquid butadiene rubber (chemical way), and combinations thereof.

In one embodiment, the toughening agent used to toughen the epoxy resin is core-shell rubber (CSR) particles. The CSR particles preferably have a D50 particle size of from 10 nm to 300 nm, more preferably from 50 nm to 200 nm. Herein, the “D50 particle size” represents a median diameter in a volume-basis particle size distribution curve obtained by measurement with a laser diffraction particle size analyzer. The CSR particles may have a soft core comprised of a polymeric material having elastomeric or rubbery properties, i.e. a glass transition temperature less than about 0° C., preferably less than about −30° C., and the said core is surrounded by a hard shell comprised of a non-elastomeric polymeric material (i.e., a thermoplastic or thermoset/crosslinked polymer having a glass transition temperature greater than ambient temperatures, e.g. greater than about 50° C.).

Specific example of the said CRS particles is a core comprised of a diene homopolymer or copolymer (for example, a homopolymer of butadiene or isoprene, a copolymer of butadiene or isoprene with one or more ethylenically unsaturated monomers such as vinyl aromatic monomers, (meth)acrylonitrile, (meth)acrylates, or the like) surrounded by shell comprised of a polymer or copolymer of one or more monomers such as (meth)acrylates (e.g., methyl methacrylate), vinyl aromatic monomers (e.g., styrene), vinyl cyanides (e.g., acrylonitrile), unsaturated acids and anhydrides (e.g., acrylic acid), (meth)acrylamides, and the like having a suitably high glass transition temperature. The polymer or copolymer used in the shell may have acid groups that are crosslinked ionically through metal carboxylate formation (e.g., by forming salts of divalent metal cations). The shell polymer or copolymer may also be covalently crosslinked by monomers having two or more double bonds per molecule. Other elastomeric polymers may also be suitably used for the core, including polybutylacrylate or polysiloxane elastomer (e.g., polydimethylsiloxane, particularly crosslinked polydimethylsiloxane). The particle may be comprised of more than two layers (e.g., a central core of one elastomeric material may be surrounded by a second core of a different elastomeric material or the core may be surrounded by two shells of different compositions or the particle may have the structure of soft core/hard shell/soft shell/hard shell). Typically, the core comprises from about 50 to about 95 percent by weight of the particle while the shell comprises from about 5 to about 50 percent by weight of the particle. Specific example of CSR particle is methyl methacrylate-Butadiene-Styrene (MBS). The CSR particles may be pre-dispersed in a liquid resin matrix system such as those available from Kaneka Corporation under the trademarks Kane Ace MX.

Suitable commercial examples of the toughened epoxy resin include MX 120 (liquid Bisphenol A epoxy with about 25 wt. % CSR), MX 125 (liquid Bisphenol A epoxy with about 25 wt. % CSR), MX 153 (liquid Bisphenol A epoxy with about 33 wt. % CSR), MX 154 (liquid Bisphenol A epoxy with about 40 wt. % CSR), MX 156 (liquid Bisphenol A epoxy with about 25 wt. % CSR), MX 130 (liquid Bisphenol F epoxy with about 25 wt. % CSR), MX 135 (liquid Bisphenol F epoxy with about 25 wt. % CSR), MX 257 (liquid Bisphenol A epoxy with about 37 wt. % CSR), MX 416 and MX 451 (liquid multifunctional epoxy with about 25 wt. % CSR), MX 215 (Epoxidized Phenol Novolac with about 25 wt. % CSR), and MX 551 (cycloaliphatic epoxy with about 25 wt. % CSR), all from Kaneka Corporation.

In some embodiments, the toughening agent used to toughen the epoxy resin can be liquid butadiene rubber. The said liquid butadiene rubber can have homo- or copolymers containing repeating units derived from butadiene or isobutadiene, or copolymers of butadiene or isobutadiene with acrylates and/or acyrlonitriles, e.g. liquid butadiene acrylonitrile rubbers. The liquid butadiene rubber used as toughening agent in the toughened epoxy resin of the present invention may contain reactive end groups, such as amino-terminated liquid nitrile rubber (ATBN) or carboxylate-terminated liquid acrylonitrile rubber (CTBN) or liquid rubbers containing free epoxy- or methacrylate end-groups. Liquid butadiene rubbers are commercially available, for example under the trade designation of HYPOX-R from CVC Thermoset, USA.

According to the present invention, the component (B) may present in an amount of from 0% to 10%, preferably from 3% to 7% by weight, based on the total weight of the composition.

### Imidazole Compound

According to the present invention, the electrically conductive adhesive composition comprises (C) at least one imidazole compound as accelerator.

Examples of the imidazole compound used in the present invention include, but not limited to, 2-heptadecylimidazole, 2-phenyl-4,5-dihydroxymethylimidazole, 2-undecylimidazole, 2-phenyl-4-methyl-5-hydroxymethylimidazole, 2-phenyl-4-benzyl-5-hydroxymethylimidazole, 2-methylimidazole, 2-phenylimidazole, 2-phenyl-4-methylimidazole, 1-cyanoethyl-2-phenylimidazole, and combinations thereof.

The imidazole compound may be used singly or in combination of two or more.

Commercial examples of the above-described imidazole compound used as accelerator in the present invention include IMICURE EMI-24 Curing Agent available from Evonik, CUREZOL 2P4MZ and Curezol 2P4MHZ PW available from Shikoku Chemicals.

According to the present invention, the component (C) may present in an amount of from 0.1% to 5% by weight, preferably from 1% to 3% by weight, based on the total weight of the composition.

Latent Amine Curing Agent Other than Imidazole Compound

According to the present invention, the electrically conductive adhesive composition comprises (D) at least one latent amine curing agent other than imidazole compound.

As used herein, “latent curing agent” refers to a curing agent that is slowly released or diffuses from a barrier at room temperature. The release or diffusion of the curing agent may be accelerated, for example at increased temperature, radiation, or force.

The use of combinations of imidazole compound and latent amine curing agent other than imidazole compound (D) in the electrically conductive adhesive composition of the present invention is advantageous because the said compositions exhibit fast curing speed and are capable of forming a good electrically conductive interconnection.

Examples of latent amine curing agent other than imidazole compound may include but not limit to amine adduct latent curing agent, preferably obtained by the reaction products of an amine compound with an epoxy compound, an isocyanate compound and/or a urea compound, core-shell type latent amine curing agent, master batch type latent amine curing agent, and combinations thereof, preferably core-shell type latent amine curing agent.

Examples of an epoxy compound used as one of raw materials for manufacturing the amine adduct latent curing agent (amine-epoxy-adduct based type latent curing agent) may include polyglycidyl ether obtained by the reaction between polyhydric phenol such as bisphenol A, bisphenol F, catechol, and resorcinol, or polyhydric alcohol such as glycerin and polyethylene glycol, and epichlorohydrin, glycidyl ether ester obtained by the reaction between hydroxycarboxylic acid such as p-hydroxybenzoic acid and 3-hydroxynaphthoic acid, and epichlorohydrin, polyglycidyl ester obtained by the reaction between polycarboxylic acid such as phthalic acid and terephthalic acid, and epichlorohydrin, and a glycidyl amine compound obtained by the reaction between 4,4′-diaminodiphenylmethane, m-aminophenol, or the like, and epichlorohydrin. Further examples may include a multifunctional epoxy compound such as an epoxidized phenol novolac resin, an epoxidized cresol novolac resin, and epoxidized polyolefin, and a monofunctional epoxy compound such as butyl glycidyl ether, phenyl glycidyl ether, and glycidyl methacrylate. However, the above-described epoxy compound using as one of raw materials for manufacturing the amine adduct latent curing agent used in the present invention is not limited to these examples.

An amine compound used as another raw material for manufacturing the amine adduct latent curing agent may be any compound which has in its molecule one or more active hydrogens which can undergo an addition reaction with an epoxy group and has in its molecule one or more functional groups selected from a primary amino group, a secondary amino group, and a tertiary amino group. Examples of such an amine compound will be indicated below. Examples thereof may include aliphatic amines such as diethylenetriamine, triethylenetetramine, n-propylamine, 2-hydroxyethyl aminopropylamine, cyclohexylamine, and 4,4′-diamino-dicyclohexylmethane, an aromatic amine compound such as 4,4′-diaminodiphenylmethane and 2-methylaniline, and a nitrogen atom-containing heterocyclic compound such as 2-ethyl-4-methylimidazole, 2-ethyl-4-methylimidazoline, 2,4-dimethylimidazoline, piperidine, and piperazine. However, the above-described amine compound using as raw material for manufacturing the amine adduct latent curing agent used in the present invention is not limited to these examples.

Examples of such a compound may include primary or secondary amines having in its molecule a tertiary amino group, such as an amine compound such as dimethylaminopropylamine, diethylaminopropylamine, di-propylaminopropylamine, dibutylaminopropylamine, dimethylaminoethylamine, diethylaminoethylamine, and N-methylpiperazine, and an imidazole compound such as 2-methylimidazole, 2-ethylimidazole, 2-ethyl-4-methylimidazole, and 2-phenylimidazole. Further examples may include alcohols, phenols, thiols, carboxylic acids, hydrazides, and the like, which have in its molecule a tertiary amino group, such as 2-dimethylaminoethanol, 1-methyl-2-dimethylaminoethanol, 1-phenoxymethyl-2-dimethylaminoethanol, 2-diethylaminoethanol, 1-butoxymethyl-2-dimethylaminoethanol, 1-(2-hydroxy-3-phenoxypropyl)-2-methylimidazole, 1-(2-hydroxy-3-phenoxypropyl)-2-ethyl4-methylimidazole, 1-(2-hydroxy-3-butoxypropyl)-2-methylimidazole, 1-(2-hydroxy-3-butoxypropyl)-2-ethyl-4-methylimidazole, 1-(2-hydroxy-3-phenoxypropyl)-2-phenylimidazoline, 1-(2-hydroxy-3-butoxypropyl)-2-methylimidazoline, 2-(dimethylaminomethyl)phenol, 2,4,6-tris(dimethylaminomethyl)phenol, N-nhydroxyethylmorpholine, 2-dimethylaminoethanethiol, 2-mercaptopyridine, 2-benzoimidazole, 2-mercaptobenzoimidazole, 2-mercaptobenzothiazole, 4-mercaptopyridine, N,N-dimethylaminobenzoic acid, N,N-dimethylglycine, nicotinic acid, isonicotinic acid, picolinic acid, N,N-dimethylglycine hydrazide, N,N-dimethylpropionic acid hydrazide, nicotinic acid hydrazide, and isonicotinic acid hydrazide. However, the above-described compound having in its molecule a tertiary amino group using as raw material for manufacturing latent amine curing agent in the present invention is not limited to these examples.

Examples of an isocyanate compound used as further another raw material of the amine adduct latent curing agent include, but not limited to, a monofunctional isocyanate compound such as n-butyl isocyanate, isopropyl isocyanate, phenyl isocyanate, and benzyl isocyanate, and a multifunctional isocyanate compound such as hexamethylene diisocyanate, toluene diisocyanate, 1,5-naphthalene diisocyanate, diphenylmethane-4,4′-diisocyanate, isophorone diisocyanate, xylyl ene diisocyanate, paraphenylene diisocyanate, 1,3,6-hexamethylene triisocyanate, and bicycloheptane triisocyanate. Furthermore, there can be used a compound containing at its terminal an isocyanate group, which is obtained by the reaction between these multifunctional isocyanate compounds and an active hydrogen compound. Examples of such a compound containing at its terminal an isocyanate group may include an adduct compound having at its terminal an isocyanate group, which is obtained by the reaction between toluene diisocyanate and trimethylolpropane, and an adduct compound having at its terminal an isocyanate group, which is obtained by the reaction between toluene diisocyanate and pentaerythritol. However, the above-described compound containing at its terminal an isocyanate group using as raw material for manufacturing amine adduct latent curing agent in the present invention is not limited to these examples.

Example of a urea compound used as a raw material for producing amine adduct latent curing agent include, but not limited to, urea, urea phosphate, urea oxalate, urea acetate, diacetyl urea, dibenzoylurea, and trimethylurea.

Commercial examples of the above-described amine adduct latent curing agent include Ajicure PN-H, Ajicure PN-40 and Ajicure PN-50 available from Ajinomoto FineTechno Co., Inc., Hardener X-3661 S and Hardener X-3670S available from A.C.R. Co., Ltd, EH-5011 S and EH5057P available from Adeka, Ancamine 2014FG and 2337S available from Evonik, FXR-1121 available from T&K Toka Corporation, Fujicure FXE-1000 and Fujicure FXR-1030 available from T&K Toka Corporation.

Further, the core-shell type latent amine curing agent is obtained by further treating the surface of an amine adducts latent curing agent with acid compounds such as a carboxylic acid compound and a sulfonic acid compound, isocyanate compounds or epoxy compounds to form a shell of a modified product (adducts, etc.) onto the surface. Further, the master batch type latent amine curing agent is the core-shell type latent curing agent in a state of being mixed with an epoxy resin.

Commercially examples of the above-described core-shell type latent amine curing agents and master batch type latent amine curing agents include Ajicure PN-23 J available from Ajinomoto FineTechno Co., Fujicure FXR 1081 available from T&K Toka Corporation, Novacure HX-3722 available from Asahi Kasei Epoxy Co., Ltd., Novacure HX-3742 available from Asahi Kasei Epoxy Co., Ltd. and Novacure HX-3613 available from Asahi Kasei Epoxy Co., Ltd.

In preferred embodiments, more than two types of the latent amine curing agents may be used in combinations.

According to the present invention, the component (D) may present in an amount of from 0.1% to 10% by weight, more preferably from 1% to 7% by weight, based on the total weight of the composition.

Silver Filler Having a D50 Particle Size of No More than 20 μm

According to the present invention, the electrically conductive adhesive composition comprises (E) at least one silver filler having a D50 particle size of no more than 20 μm as electrically conductive filler.

As used herein, “D50 particle size” represents a median diameter in a volume-basis particle size distribution curve obtained by measurement with a laser diffraction particle size analyzer preferably using a Microtrac S3500 available from Microtrac Retsch GmbH. In this technique, the size of particles in suspensions or emulsions is measured using the diffraction of a laser beam, based on application of either Fraunhofer or Mie theory. In the present invention, Mie theory or a modified Mie theory for non-spherical particles is applied and the average particle sizes or D50 values relate to scattering measurements at an angle from 0.02 to 135 degrees relative to the incident laser beam.

In preferred embodiments, the silver filler has a D50 particle size of from no more than 9 μm, more preferably from 1 μm to 9 μm. Using silver filler having a D50 particle size of the above range as electrically conductive fillers in the electrically conductive adhesive compositions of the present invention is advantageous, because said particles allow forming a stable and reliable electrical interconnection between two substrates.

In preferred embodiments, the component (E) used in the electrically conductive adhesive composition of the present invention include particles in which the shape is flake. The component (E) having such a shape has high contact area between the fillers, which may reduce voids in a cured product. The shape of silver filler is a shape when analyzed from scanning electron microscope (SEM) observation, and Philips XL30 can be used as the observation apparatus of SEM. Examples of the flake silver fillers include particles with a shape called tabular, dished, scaly, and flaky. When flake silver fillers are brought into contact with each other, the contact area increases compared with the case where granular silver fillers are brought into contact with each other. Therefore, if curing the electrically conductive adhesive composition of the present invention containing component (E) which shape is flake, the denseness of component (E) will increase, and as a result, the electrical conductivity of a cured product of the electrically conductive adhesive composition of the present invention is improved.

The silver fillers having a D50 particle size of no more than 20 μm may be used singly or in combination of two or more. Combination of silver fillers having a D50 particle size of no more than 10 μm in different shapes or different sizes may reduce porosity of the cured product. In a preferred embodiment, a mixture of flake-shaped silver filler having a D50 particle size of from 1 to 9 μm and a flake-shaped silver filler having a D50 particle size of from 1 to 5 μm is used in the electrically conductive adhesive composition of the present invention.

In some embodiments, the component (E) having a tap density of 2 g/cm³ to 15 g/cm³, more preferably of 3 g/cm³ to 7.5 g/cm³ can be used to prepare the electrically conductive adhesive composition of the present invention.

The tap density is determined in accordance with ISO 3953:1993. The principle of the method specified is tapping a specified amount of powder in a container by means of a tapping apparatus until no further decrease in the volume of the powder takes place. The mass of the powder divided by its volume after the test gives its tap density.

The silver filler having a D50 particle size of no more than 20 μm used in the electrically conductive adhesive composition of the present invention can be manufactured by a known method such as a reduction method, a milling method, an electrolysis method, an atomization method, or a heat treatment method.

It is possible to use commercially available silver fillers having a D50 particle size of no more than 20 μm in the present invention. Examples thereof include TC-505C available from Tokuriki Chemical Research Co., Ltd., FA-SAB 238 available from Dowa Hightech, KP 60 available from Ames Goldsmith and SA-0201 available from Metalor.

According to the present invention, the component (E) may present in an amount of from 35% to 90% by weight, more preferably from 40% to 80% by weight, based on the total weight of the composition. By using such range amount of component (E) in the present composition, the cured products of said electrically conductive adhesive compositions can be obtained with good electrical conductivity.

Silver Filler Having a D50 Particle Size of from 20 to 100 μm

According to the present invention, the electrically conductive adhesive composition of the present invention comprises (F) at least one silver filler having a D50 particle size of from 20 to 100 μm which serves as “spacer” to prevent the adhesive from squeezing out of the overlapping region of the PV module as a result of compression between two busbar surfaces during shingling process.

In preferred embodiments, the component (F) can be at least one silver filler having a D50 particle size of from 20 to 70 μm, more preferably from 20 to 50 μm. Using silver fillers having such range of D50 particle size can achieve a smaller adhesive width when cured than electrically conductive adhesive compositions without containing the same.

In preferred embodiments, the component (F) used in the electrically conductive adhesive composition include silver fillers having a D50 particle size of from 20 to 100 μm in which the shape is spherical. The shape of silver filler is a shape when analyzed from scanning electron microscope (SEM) observation, and Philips XL30 can be used as the observation apparatus of SEM. Spherical silver fillers having a D50 particle size of from 20 to 100 μm can act as “pillars” between two busbars of PV cells to prevent adhesive compositions of the present invention from squeezing out of the overlapping region of the PV cells as a result of compression between two busbar surfaces during shingling process.

There are many physical and chemical methods which universally have been applied to prepare the component (F), such as milling, atomization, thermal decomposition, electrochemical process, and chemical reduction process. Taking atomization for an example, it is a process to powder melted silver using high-speed fluid for dispersion and coagulation. The shape of the powder can be spherical, granular, nodular, or irregular according to the surface tension of the atomized silver and the atomization conditions.

In another embodiment, component (F) having a tap density of 2 g/cm³ to 15 g/cm³, more preferably of 5 g/cm³ to 8 g/cm³ can be used to prepare electrically conductive adhesive composition of the present invention.

It is possible to use commercially available silver fillers having a D50 particle size of from 20 to 100 μm in the present invention. Examples thereof include Silver Powder 81-636, Silver Powder 81-451 and Silver Powder 81-330 available from Technic Inc.

According to the present invention, the component (F) may present in an amount of from 0.1% to 10% by weight, more preferably from 1% to 10% by weight, even more preferably from 1% to 5% by weight, based on the total weight of the composition.

In preferred embodiments, the electrically conductive adhesive composition does not comprise any silver filler having a D50 particle size different to component (E) or (F). In more preferred embodiments, the electrically conductive adhesive composition does not comprise any silver filler having a D50 particle size of larger than 100 μm.

### Epoxy Diluent

According to the present invention, the electrically conductive adhesive composition of the present invention may optionally comprise (G) at least one epoxy diluent, preferably glycidyl ether-based diluent.

Suitable examples of the epoxy diluents are monoglycidyl ethers, such as phenyl glycidyl ether, alkyl phenol monoglycidyl ether, aliphatic monoglycidyl ether, alkylphenol mono glycidyl ether, alkylphenol monoglycidyl ether, 3-glycidoxypropyl trimethoxysilane, 3-glycidoxypropyl trimethoxysilane, 3-glycidoxypropylmethyldimethoxysilane; diglycidyl ethers, such as 1,4-butanediol diglycidyl ether, 1,4-cyclohexane-dimethanol, the diglycidyl ether of resorcinol, diglycidyl ether of cyclohexane dimethanol, diglycidyl ether of neopentyl glycol, triglycidyl ether of trimethylolpropane dipentene, and the divinyl ether of cyclohexanedimethanol; and tri- or tetra-glycidyl ethers, such as trimethylolpropane triglycidyl ether, glycerin triglycidyl ether, and pentaerythritol tetraglycidyl ether.

Suitable commercially available epoxy diluents are for example under the trade name of NC-513, Lite 2513HP (both from Cardolite Corporation), ADEKA ED-502S, ED-509, ED-529, ED-506, ED-503, ED523T, ED-505, ED-505R, ED-507 and ED-509E (all from Adeka Corporation), DY-C, DY-D, DY-E, DY-F, DY-H, DY-K, DY-L, DY-P, DY-T, DY 3601, and DY-CNO (all from Huntsman Corporation), Heloxy modifier 48, Heloxy modified 62 and Heloxy modified 65 (all from Hexion Corporation) and Vikolox 14 (from Arkema).

According to the present invention, the component (G) may present in an amount of from 0% to 20% by weight, more preferably from 7% to 15% by weight, based on the total weight of the composition.

### Additive

In another embodiment the electrically conductive adhesive composition of the present invention further comprises one or more additives, such as coupling agent, plasticizers, oils, stabilizers, antioxidants, anti-corrosion agents, chelating agents, pigments, dyestuffs, polymeric additives, defoamers, preservatives, thickeners, rheology modifiers, humectants, adhesion promoters, dispersing agents, water, and combinations thereof.

When used, additives are used in an amount sufficient to provide the desired properties. At least one additive may be present in the adhesive composition of the present invention in an amount in the range of from 0.05% to 10% by weight, preferably in an amount in the range of from 0.1% to 5%, and more preferably in an amount in the range of from 0.1% to 1% by weight, based on the total weight of the composition.

### Composition

In particular preferred embodiments, the electrically conductive adhesive composition, based on the total weight of the composition, comprises:
(A) from 5% to 30% by weight, preferably from 12% to 20% by weight of at least one non-toughened epoxy resin,
(B) from 0% to 10%, preferably from 3% to 7% by weight of at least one toughened epoxy resin,
(C) from 0.1% to 5% by weight, preferably from 1% to 3% by weight of at least one imidazole compound,
(D) from 0.1% to 10% by weight, more preferably from 1% to 7% by weight of latent amine curing agent other than imidazole compound,
(E) from 35% to 90% by weight, more preferably from 40% to 80% by weight, of at least one silver filler having a D50 particle size of no more than 20 μm,
(F) from 0.1% to 10% by weight, more preferably from 1% to 10% by weight, even more preferably from 1% to 5% by weight of at least one silver filler having a D50 particle size of from 20 to 100 μm,
(G) from 0% to 20% by weight, more preferably from 7% to 15% by weight of epoxy diluent, and
(H) from 0.1% to 5%, and more preferably in an amount in the range of from 0.1% to 1% by weight of additive.

### Preparation Method of the Electrically Conductive Adhesive Composition

The electrically conductive adhesive composition according to the present invention can be prepared at room temperature by mixing all components (A) to (H) and stirring the mixture uniformly to obtain the composition.

In preferred embodiments, the electrically conductive adhesive composition can be prepared by steps as follows:
Step (1): if component (G) is present, mixing component (G) with component (A) until homogenous mixture is obtained,
Step (2): if component (B) is present, added component (B) into the mixture obtained from Step (1) and mixing by a roll mixer,
Step (3): adding component (C) and component (D) to further mix,
Step (4): adding component (E) and followed by component (F) to mix by a roll mixer, and
Step (5): if any additive is present, adding additives to mix lastly.

The apparatuses for these mixing, stirring, dispersing, and the like are not particularly limited. There can be used an automated mortar, a Henschel mixer, a three-roll mill, a ball mill, a planetary mixer, a bead mill, and the like which are equipped with a stirrer and a heater. Also, an appropriate combination of these apparatuses may be used. The preparation method of the electrically conductive adhesive is not particularly limited, as long as a composition in which the above-described components are uniformly mixed can be obtained.

### Curing Profile and Cured Product

A further aspect of the present invention is the cured product of the electrically conductive adhesive composition of the present invention. The electrically conductive adhesive composition of the present invention can be cured in from 0.1 s to 180 minutes at a temperature within the range of from 50° C. to 250° C., preferably within the range of from 70° C. to 220° C., and more preferably within the range of from 100° C. to 220° C.

In a preferred embodiment, the electrically conductive adhesive composition of the present invention can be cured from 120° C. to 220° C. in less than 60 minutes, preferably less than 10 minutes, and more preferably less than 1 minute. The curing of the electrically conductive adhesive composition of the present invention can be performed by heating the formulation, e.g. by using IR lamps or conventional heating technique.

As will be understood, the time and temperature curing profile for each electrically conductive adhesive composition will vary, and different compositions can be designed to provide the curing profile that will be suited to the particularly industrial manufacturing process.

### Bonded Assembly, PV Module and Method of Interconnecting Two Shingled PV Cells

The third aspect of the present invention is a bonded assembly comprising two substrates aligned in a spaced apart relationship, each of which having an inwardly facing surface and an outwardly facing surface, wherein between the inwardly facing surfaces of each of the two substrates an electrically conductive bond is formed by the cured product of the electrically conductive adhesive composition of the present invention.

The term “substrate”, as used herein, preferably refers to an electrode or busbar of PV cell, wherein the inwardly facing surface of the busbar is in contact with each other bonded by the cured product of the electrically conductive adhesive of the present invention.

At least one of the substrates can be selected from metals, such as metal firing pastes, aluminum, tin, molybdenum, silver, and conductive metal oxides such as indium tin oxide (ITO), fluorine doped tin oxide, aluminum doped zinc oxide etc. Further suitable metals include copper, gold, palladium, platinum, aluminum, indium, silver coated copper, silver coated aluminum, tin, and tin coated copper. Preferably both substrates are selected from one of the aforementioned materials.

According to a fourth aspect of the invention, provided is a PV module, comprising a series-connected string of at least two PV cells in a shingle pattern having an electrically conductive adhesive composition of the present invention bonding between at least two PV cells.

According to a fifth aspect of the invention, provided is a method of interconnecting two PV cells is provided, comprising:
Step 1: providing a first PV cell on a flat surface;
Step 2: applying the electrically conductive adhesive composition of the present invention on the front busbar of the first PV cell;
Step 3: providing a second PV cell in a partial overlapping manner, such that the rear busbar of the second PV cell comes into contact with the front busbar of the first PV cell having the said electrically conductive adhesive composition bonding in between, and
Step 4: curing the said electrically conductive adhesive composition.

In some embodiments, the interconnecting method also includes, but not limited to: 1) to establish connection between PV cells, 2) to establish connection between shingled PV strings; 3) to establish connection between PV cell and other components; 4) to establish connection to external circuitry, within a shingled PV module.

The interconnecting method of the present invention can be performed by manual human intervention, standalone equipment, fully automatic equipment or any combinations thereof.

Once the electrically conductive adhesive composition can be cured, the electrically conductive adhesive composition of the present invention is contained within the overlapping region only. The width of the overlapping region is preferably between 0.1 mm to 1.0 mm.

The electrically conductive adhesive of the present invention can be applied to a substrate using any suitable application method including, e.g., automatic fine line dispensing, jet dispensing, slot die coating, roll coating, gravure coating, transfer coating, pattern coating, screen printing, spray coating, filament coating, by extrusion, air knife, trailing blade, brushing, dipping, doctor blade, offset gravure coating, rotogravure coating, and combinations thereof. The electrically conductive adhesive can be applied as a continuous or discontinuous coating, in a single or multiple layers and combinations thereof.

According to the sixth aspect of the invention, use of the electrically conductive adhesive composition according to the present invention or the cured product of the present invention in the manufacturing of PV module or solar panels.

### EXAMPLES

The following examples are intended to assist one skilled in the art to better understand and practice the present invention. The scope of the invention is not limited by the examples but is defined in the appended claims. All parts and percentages are based on weight unless otherwise stated.

### Raw Materials:

Epotohto ZX 1059 is a mixture of 50% by weight of bisphenol A type epoxy resin and 50% by weight of bisphenol F type epoxy resin based on total weight of composition, available from Nippon Steel chemical Co., Ltd.

MARPROOF G-0150M is an (meth)acrylate group-containing epoxy resin, available from NOF Corporation.

Kane Ace MX 135 is Bisphenol F type epoxy resin toughened by about 25 wt. % core shell rubber, available from Kaneka Corporation.

ADEKA ED-509E is epoxy diluent, available from Adeka Corporation.

Vikolox 14 is epoxy diluent, available from Arkema.

CUREZOL 2P4MZ is an imidazole curing agent, available from Shikoku Chemicals.

Curezol 2P4MHZ PW is 2-phenyl-4-methyl-5-hydroxymethylimidazole, available from Shikoku Chemicals.

Ajicure PN-H is amine adduct latent curing agent, available from Ajinomoto Fine-Techno Co., Inc.

Ajicure PN-23 J is micro-pulverized amine adduct latent curing agent, available from Ajinomoto Fine-Techno Co., Inc.

Silquest A-187 is silane resin, available from Momentive Performance Materials.

KP 60 is silver filler having a D50 particle size of 9 μm, available from Ames Goldsmith.

SA-0201 is silver filler having a D50 particle size of 2.7 μm, available from Metalor.

Silver Powder 81-636 is silver filler having a D50 particle size of 22.7 μm, available from Technic Inc.

Silver Powder 81-451 is silver filler having a D50 particle size of 39.9 μm, available from Technic Inc.

Silver Powder 81-330 is silver filler having a D50 particle size of 48.1 μm, available from Technic Inc.

### Preparation Method

### Example 1 (Ex.1)

6.304 g Glycirol ED 509 E and 3.152 g MARPROOF G-0150M were mixed in 250 rpm at 80° C. on a hot plate until the solid resin is completely dissolved in the epoxy diluent, and then added 5.516 g Kane Ace™ MX 135 and 3.6248 g Vikolox 14 to mix for 10 minutes for later use (mixture A). 4.728 g Epotohto ZX 1059, 1.182 g CUREZOL 2P4MZ and 0.394 g Curezol 2P4MHZ PW were pre-mixed by a ross mixer for 5 minutes and three roll mills for 2 times for later use (mixture B). Another 9.456 g Epotohto ZX 1059, 3.94 g Ajicure PN-H and 0.788 g Ajicure PN-23 J were pre-mixed in the same way for later use (mixture C). Mixture A, mixture B and mixture C were mixed by a ross mixer for another 5 minutes. Then added 29.55 g SA 0201 into the obtained mixture and mixing by a ross mixer for 10 minutes. After that, added 29.55 g KP 60 to mix by a ross mixer for 10 more minutes. Then added 1.5 g Silver Powder 81-636 to mix by a ross mixer for 10 more minutes. After that, added 0.3152 g Silquest A-187 to mix by a ross mixer for 5 more minutes. Lastly, the final mixture was mixed by the ross mixer for 40 minutes while degassing to achieve the composition.

### Example 2 (Ex.2)

6.24 g Glycirol ED 509 E and 3.12 g MARPROOF G-0150M were mixed in 250 rpm at 80° C. on a hot plate until the solid resin is completely dissolved in the epoxy diluent, and then added 5.46 g Kane Ace™ MX 135 and 3.588 g Vikolox 14 to mix for 10 minutes for later use (mixture A). 4.632 g Epotohto ZX 1059, 1.17 g CUREZOL 2P4MZ and 0.39 g Curezol 2P4MHZ PW were pre-mixed by a ross mixer for 5 minutes and three roll mills for 2 times for later use (mixture B). Another 9.264 g Epotohto ZX 1059, 3.9 g Ajicure PN-H and 0.78 g Ajicure PN-23 J were pre-mixed in the same way for later use (mixture C). Mixture A, mixture B and mixture C were mixed by a ross mixer for another 5 minutes. Then added 29.25 g SA 0201 into the obtained mixture and mixing by a ross mixer for 10 minutes. After that, added 29.25 g KP 60 to mix by a ross mixer for 10 more minutes. Then added 2.5 g Silver Powder 81-636 to mix by a ross mixer for 10 more minutes. After that, added 0.312 g Silquest A-187 to mix by a ross mixer for 5 more minutes. Lastly, the final mixture was mixed by the ross mixer for 40 minutes while degassing to achieve the composition.

### Example 3 (Ex.3)

6.176 g Glycirol ED 509 E and 3.088 g MARPROOF G-0150M were mixed in 250 rpm at 80° C. on a hot plate until the solid resin is completely dissolved in the epoxy diluent, and then added 5.404 g Kane Ace™ MX 135 and 3.5512 g Vikolox 14 to mix for 10 minutes for later use (mixture A). 4.68 g Epotohto ZX 1059, 1.158 g CUREZOL 2P4MZ and 0.386 g Curezol 2P4MHZ PW were pre-mixed by a ross mixer for 5 minutes and three roll mills for 2 times for later use (mixture B). Another 9.36 g Epotohto ZX 1059, 3.86 g Ajicure PN-H and 0.772 g Ajicure PN-23 J were pre-mixed in the same way for later use (mixture C). Mixture A, mixture B and mixture C were mixed by a ross mixer for another 5 minutes. Then added 28.95 g SA 0201 into the obtained mixture and mixing by a ross mixer for 10 minutes. After that, added 28.95 g KP 60 to mix by a ross mixer for 10 more minutes. Then added 3.5 g Silver Powder 81-636 to mix by a ross mixer for 10 more minutes. After that, added 0.3088 g Silquest A-187 to mix by a ross mixer for 5 more minutes. Lastly, the final mixture was mixed by the ross mixer for 40 minutes while degassing to achieve the composition.

### Example 4 (Ex.4)

6.24 g Glycirol ED 509 E and 3.12 g MARPROOF G-0150M were mixed in 250 rpm at 80° C. on a hot plate until the solid resin is completely dissolved in the epoxy diluent, and then added 5.46 g Kane Ace™ MX 135 and 3.588 g Vikolox 14 to mix for 10 minutes for later use (mixture A). 4.68 g Epotohto ZX 1059, 1.17 g CUREZOL 2P4MZ and 0.39 g Curezol 2P4MHZ PW were pre-mixed by a ross mixer for 5 minutes and three roll mills for 2 times for later use (mixture B). Another 9.36 g Epotohto ZX 1059, 3.9 g Ajicure PN-H and 0.78 g Ajicure PN-23 J were pre-mixed in the same way for later use (mixture C). Mixture A, mixture B and mixture C were mixed by a ross mixer for another 5 minutes. Then added 29.25 g SA 0201 into the obtained mixture and mixing by a ross mixer for 10 minutes. After that, added 29.25 g KP 60 to mix by a ross mixer for 10 more minutes. Then added 2.5 g Silver Powder 81-451 to mix by a ross mixer for 10 more minutes. After that, added 0.312 g Silquest A-187 to mix by a ross mixer for 5 more minutes. Lastly, the final mixture was mixed by the ross mixer for 40 minutes while degassing to achieve the composition.

### Example 5 (Ex.5)

6.24 g Glycirol ED 509 E and 3.12 g MARPROOF G-0150M were mixed in 250 rpm at 80° C. on a hot plate until the solid resin is completely dissolved in the epoxy diluent, and then added 5.46 g Kane Ace™ MX 135 and 3.588 g Vikolox 14 to mix for 10 minutes for later use (mixture A). 4.8 g EpotohtoZX 1059, 1.17 g CUREZOL 2P4MZ and 0.39 g Curezol 2P4MHZ PW were pre-mixed by a ross mixer for 5 minutes and three roll mills for 2 times for later use (mixture B). Another 9.6 g Epotohto ZX 1059, 3.9 g Ajicure PN-H and 0.78 g Ajicure PN-23 J were pre-mixed in the same way for later use (mixture C). Mixture A, mixture B and mixture C were mixed by a ross mixer for another 5 minutes. Then added 29.25 g SA 0201 into the obtained mixture and mixing by a ross mixer for 10 minutes. After that, added 29.25 g KP 60 to mix by a ross mixer for 10 more minutes. Then added 2.5 g Silver Powder 81-330 to mix by a ross mixer for 10 more minutes. After that, added 0.312 g Silquest A-187 to mix by a ross mixer for 5 more minutes. Lastly, the final mixture was mixed by the ross mixer for 40 minutes while degassing to achieve the composition.

### Comparative Example 1 (CE.1)

6.4 g Glycirol ED 509 E and 3.2 g MARPROOF G-0150M were mixed in 250 rpm at 80° C. on a hot plate until the solid resin is completely dissolved in the epoxy diluent, and then added 5.6 g Kane Ace™ MX 135 and 3.68 g Vikolox 14 to mix for 10 minutes for later use (mixture A). 4.8 g Epotohto ZX 1059, 1.2 g CUREZOL 2P4MZ and 0.4 g Curezol 2P4MHZ PW were pre-mixed by a ross mixer for 5 minutes and three roll mills for 2 times for later use (mixture B). Another 9.6 g Epotohto ZX 1059, 4 g Ajicure PN-H and 0.8 g Ajicure PN-23 J were pre-mixed in the same way for later use (mixture C). Mixture A, mixture B and mixture C were mixed by a ross mixer for another 5 minutes. Then added 30 g SA 0201 into the obtained mixture and mixing by a ross mixer for 10 minutes. After that, added 30 g KP 60 to mix by a ross mixer for 10 more minutes. After that, added 0.2 g Silquest A-187 to mix by a ross mixer for 5 more minutes. Lastly, the final mixture was mixed by the ross mixer for 40 minutes while degassing to achieve the composition.

### Test Methods:

### Volume Resistivity

The volume resistivity was determined in the following manner: aliquots of the prepared formulations were drawn down the surface of glass slides giving strips with strip dimensions of about 5 cm in length, 2.5 mm in width and approximately 30-40 microns in thickness, and then followed by heated at 150° C. in an oven for 15 minutes to cure. Glass plates were cooled to room temperature before measurement. Resistance was determined by measuring the voltage (V) drop along a 5 cm strip while passing current (I) through the strip, (R=V/1). Three separate strips were prepared and measured for resistance and dimensions. The volume resistivity (Rv) was calculated for each strip using the formula Rv=(R(w)(t)/L) where R is the electrical resistance of the sample in Ohms measured using an ohmmeter or equivalent resistance measuring device, w and t are the width and thickness of the sample, in centimeters, and L is the distance in centimeters between the electrical conductors of the resistance measuring device. Volume resistivity units were reported in Ohm-cm. Volume resistivity less than 5E-03 is considered as acceptable.

### Contact Resistivity

The electrical contact resistivity between the aliquots of the prepared formulations and silver was measured in the following manner: the resistance of the two silver plates was measured in advance and recorded as Rₛᵢₗᵥₑᵣ₁ and Rₛᵢₗᵥₑᵣ₂. The aliquots of the prepared formulations giving strips across the length of the silver test plate and was followed by covering another silver plate on the formulations. Then samples were cured in an oven at 150° C. for 20 minutes. After curing and cooling down to 20° C. the electrical contact resistance was measured across 50 pairs of electrodes. The resistance between two silver plates were recorded as R. The contact resistivity Rc was calculated using the equation Rc=S*(R−Rₛᵢₗᵥₑᵣ₁−Rₛᵢₗᵥₑᵣ₂−V_{Ra})/2, where S was the contact area between the silver plate and formulations, Rₛᵢₗᵥₑᵣ₁ and Rₛᵢₗᵥₑᵣ₂ were the resistance of the two silver plates, and V_{Ra} was the volume resistivity of the formulations. The average contact resistance (arithmetic average) was reported in mOhm·cm². The average contact resistance less than 0.1 mOhm·cm² is considered as acceptable.

### Adhesive Width and Squeeze-Out Test

Each formulation of the present invention and the comparative example was printed on the surface of front busbar of one PV cell and the surface of rear busbar of another PV cell by using a stencil with 200 microns in width and 100 microns in thickness. The two PV cells were bonded together with an overlapping region in a width of 1.0 mm through a shingle machine to form a PV module. Then the PV module was heated at 180° C. for 30 seconds to cure the adhesive compositions of the present invention and the comparative example. The width of the cured adhesives of each formulation was measured and recorded by using X-ray. To ensure the cured adhesive would not squeeze out of the overlapping region in a width of 1.0 mm, the cured adhesive's width must be less than 0.85 mm. Therefore, the width of the cured adhesives larger than 0.85 mm would be recorded as “NOT PASS” the squeeze-out test.

The test results are shown in Table 1.

| | Ex. 1 | Ex. 2 | Ex. 3 | Ex. 4 | Ex. 5 | CEx. 1 |
|---|---|---|---|---|---|---|
| Volume | 1.10E−03 | 1.20E−03 | 1.20E−03 | 1.20E−03 | 1.00E−03 | 1.40E−03 |
| resistivity | | | | | | |
| (Ohm · cm) | | | | | | |
| Contact | 0.06 | 0.05 | 0.05 | 0.05 | 0.05 | 0.05 |
| resistivity | | | | | | |
| (mOhm · cm²) | | | | | | |
| Adhesive width | 0.64 | 0.64 | 0.54 | 0.57 | 0.54 | 0.9 |
| (mm) | | | | | | |
| Squeeze- out | PASS | PASS | PASS | PASS | PASS | NOT PASS |
| test | | | | | | |

As can be seen from Table 1, the electrically conductive adhesive compositions of the present invention passed the squeeze-out test and exhibited good volume resistance and contact resistance when cured, while the comparative composition did not pass the squeeze-out test.

Although some preferred embodiments have been described, many modifications and variations may be made thereto in light of the above teachings. It is therefore to be understood that the invention may be practiced otherwise than as specifically described without departing from the scope of the appended claims.

What is claimed is:

1. An electrically conductive adhesive composition comprising:
(A) at least one non-toughened epoxy resin,
(B) optionally at least one toughened epoxy resin,
(C) at least one imidazole compound,
(D) at least one latent amine curing agent other than imidazole compound,
(E) at least one silver filler having a D50 particle size of no more than 20 μm, and
(F) at least one silver filler having a D50 particle size of from 20 to 100 μm.

2. The electrically conductive adhesive composition according to claim 1, wherein the component (A) is selected from non-toughened epoxy resin having no (meth)acrylate group, non-toughened epoxy resin containing (meth)acrylate group, halides thereof and hydrides thereof, bisphenol A based diglycidyl ethers, bisphenol F based diglycidyl ethers, glycidyl (meth)acrylate, and combinations thereof.

3. The electrically conductive adhesive composition according to claim 1, wherein the component (B) is at least one toughened epoxy resin toughened by at least one toughening agent selected from core-shell rubber, liquid butadiene rubber, and combinations thereof.

4. The electrically conductive adhesive according to claim 1, wherein the component (C) is selected from 2-heptadecylimidazole, 2-phenyl-4,5-dihydroxymethylimidazole, 2-undecylimidazole, 2-phenyl-4-methyl-5-hydroxymethylimidazole, 2-phenyl-4-benzyl-5-hydroxymethylimidazole, 2-methylimidazole, 2-phenylimidazole, 2-phenyl-4-methylimidazole, 1-cyanoethyl-2-phenylimidazole, and combinations thereof.

5. The electrically conductive adhesive composition according to claim 1, wherein the component (D) is selected from amine adduct latent amine curing agent; core-shell type latent amine curing agent; master batch type latent amine curing agent; and combinations thereof.

6. The electrically conductive adhesive composition according to claim 1, wherein component (E) preferably has a D50 particle size of no more than 9 μm.

7. The electrically conductive adhesive composition according to claim 1, wherein component (F) has a D50 particle size of from 20 to 70 μm.

8. The electrically conductive adhesive composition according to claim 1, wherein the composition further comprises (G) at least one epoxy diluent selected from monoglycidyl ethers, diglycidyl ethers, triglycidyl ethers, and combinations thereof.

9. The electrically conductive adhesive composition according to claim 1, wherein the composition further comprises (H) at least one additive selected from coupling agent, plasticizer, oil, stabilizer, antioxidant, anti-corrosion agent, chelating agent, pigment, dyestuff, polymeric additive, defoamer, preservative, thickener, rheology modifier, humectant, adhesion promoter, dispersing agent, water, and combinations thereof.

10. The electrically conductive adhesive composition according to claim 1, wherein the component (A) is present in an amount of from 5% to 30% by weight based on the total weight of the composition.

11. The electrically conductive adhesive composition according to claim 1, wherein the component (B) is present in an amount of from 0.1% to 10% based on the total weight of the composition.

12. The electrically conductive adhesive composition according to claim 1, wherein the component (C) is present in an amount of from 0.1% to 5% by weight based on the total weight of the composition.

13. The electrically conductive adhesive composition according to claim 1, wherein the component (D) is present in an amount of from 0.1% to 10% by weight based on the total weight of the composition.

14. The electrically conductive adhesive composition according to claim 1, wherein the component (E) is present in an amount of from 35% to 90% by weight based on the total weight of the composition.

15. The electrically conductive adhesive composition according to claim 1, wherein the component (F) is present in an amount of from 0.1% to 10% by weight based on the total weight of the composition.

16. Cured products of the electrically conductive adhesive composition according to claim 1.

17. A bonded assembly comprising two substrates aligned in a spaced apart relationship, each of which having an inwardly facing surface and an outwardly facing surface, wherein between the inwardly facing surfaces of each of the two substrates is an electrically conductive bond formed by the cured product of claim 16.

18. A photovoltaic module, comprising a series-connected string of at least two photovoltaic cells in a shingle pattern having an electrically conductive adhesive composition according to claim 1 bonding between at least two photovoltaic cells.

19. A method of interconnecting two photovoltaic cells, comprising:
(1) providing a first photovoltaic cell on a flat surface;
(2) applying an electrically conductive adhesive composition according to claim 1 on the front busbar of the first photovoltaic cell;
(3) providing a second photovoltaic cell in a partial overlapping manner, such that the rear busbar of the second photovoltaic cell comes into contact with the front busbar of the first photovoltaic cell having the said electrically conductive adhesive composition bonding in between, and
(4) curing the said electrically conductive adhesive composition.
